(19) United States
(12) Patent Application Publication
(10) Pub. No.: US 2024/0348182 A1
(43) Pub. Date: Oct. 17, 2024

(54) POWER CONVERSION DEVICE

(71) Applicant: Mitsubishi Electric Corporation, Tokyo (JP)

(72) Inventor: Chiharu MORISAKI, Tokyo (JP)

(73) Assignee: Mitsubishi Electric Corporation, Tokyo (JP)

(21) Appl. No.: 18/421,368

(22) Filed: Jan. 24, 2024

(30) Foreign Application Priority Data
Apr. 13, 2023 (JP) 2023-065394

(51) Int. Cl. H02M 7/5387; H02M 1/088; H02M 1/32; H02M 7/217

(52) U.S. Cl. CPC H02M 7/53871; H02M 1/088; H02M 1/32; H02M 7/2173

(57) ABSTRACT

This power conversion device having a semiconductor switching element having a first main electrode, a second main electrode, and a gate includes: a first diode having a cathode connected to the first main electrode; a second diode having an anode and a cathode respectively connected to an anode of the first diode and the gate; and a current source which supplies current through a connection point between the anode of the first diode and the anode of the second diode, in a direction from each of the anode of the first diode and the anode of the second diode toward the corresponding cathode. When a voltage of the connection point between the first diode and the second diode is higher than a threshold voltage, short-circuit is determined to have occurred in the semiconductor switching element, and the gate is set to have an OFF voltage.

### BACKGROUND OF THE INVENTION

### 1. Field of the Invention

The present disclosure relates to a power conversion device.

### 2. Description of the Background Art

For a power conversion device for driving a motor of an automobile or the like, various short-circuit detection methods for a semiconductor switching element as a main part of the power conversion device have been proposed. For example, as disclosed in Patent Document 1, a method for performing determination as to occurrence of short-circuit by detecting whether or not the voltage on the high-potential side of a semiconductor switching element has become an abnormal high voltage that could not be generated in an ordinary ON state has been known as a short-circuit detection function for a semiconductor switching element. This method is called a DESAT method. In this method, a drain voltage is high during a period from the time point at which a gate voltage of the semiconductor switching element starts to be increased to the time point at which the gate voltage reaches a mirror voltage, and thus erroneous determination of short-circuit needs to be prevented during this period.

To this end, for example, Patent Document 1 discloses a method for preventing erroneous determination by suspending short-circuit determination during a predetermined time from the time point at which the gate voltage starts to be increased. However, in this method, variation among semiconductor switching elements leads to the following problem. That is, when the turn-on speed of each of the semiconductor switching elements is high, a time period during which short-circuit determination is suspended occurs even though short-circuit current has started to flow owing to a failure. As a result, short-circuit loss that is generated in the semiconductor switching element is increased.

Against this problem, for example, Patent Document 2 discloses a method in which: a circuit for determining a gate voltage is provided; and transition to short-circuit determination is performed after the gate voltage reaches an ON voltage. In this method, short-circuit determination is started according to the turn-on speed, and thus short-circuit detection can be expected to be achieved in a relatively shorter time than in the method in Patent Document 1 in which the predetermined time is provided. However, in general, a comparator used for determining a voltage has a response delay of about 100 to 200 ns depending on components thereof. This delay is a direct factor in increasing the short-circuit loss, and thus there is still room for enhancement regarding a time for short-circuit detection from the viewpoint of protecting a semiconductor switching element from short-circuit.
Patent Document 1: WO2014/115272A1
Patent Document 2: JP2021-57976A

As semiconductor switching elements that need to be protected through quick detection of short-circuit, there are wide-bandgap semiconductors (SiC, GaN, and the like) which are becoming widespread particularly in recent years and which are characterized by allowing a larger amount of current to flow upon short-circuit. In the case of a wide-bandgap semiconductor, the above delay in short-circuit detection is required to be further decreased.

### SUMMARY OF THE INVENTION

The present disclosure has been made to solve the above problems, and an object of the present disclosure is to provide a power conversion device that can, during a switching operation of a semiconductor switching element, prevent erroneous determination of short-circuit and detect short-circuit in a short time.

A power conversion device according to the present disclosure is a power conversion device which has a semiconductor switching element having a first main electrode, a second main electrode, and a gate and which controls a voltage of the gate with the second main electrode as a reference, to perform ON/OFF control for current flowing between the first main electrode and the second main electrode and perform power conversion between DC power and AC power, the power conversion device including:
a first diode having a cathode connected to the first main electrode;
a second diode having an anode and a cathode respectively connected to an anode of the first diode and the gate;
a current source which supplies current through a connection point between the anode of the first diode and the anode of the second diode, in a direction from each of the anode of the first diode and the anode of the second diode toward the corresponding cathode;
drive circuitry which controls the voltage of the gate of the semiconductor switching element; and
short-circuit determination circuitry which determines whether or not short-circuit has occurred in the semiconductor switching element, wherein
the short-circuit determination circuitry determines, when a voltage of the connection point between the first diode and the second diode is higher than a threshold voltage, that short-circuit has occurred in the semiconductor switching element, and
the drive circuitry sets, when the short-circuit determination circuitry determines that short-circuit has occurred, the voltage of the gate to a voltage for turning off the semiconductor switching element.

The power conversion device according to the present disclosure makes it possible to provide a power conversion device that can prevent erroneous determination and detect short-circuit in a short time.

### BRIEF DESCRIPTION OF THE DRAWINGS

FIG. 1 is a circuit diagram showing a schematic configuration of a power conversion device according to a first embodiment;

FIG. 2 is a circuit diagram showing an example of a main section of the power conversion device according to the first embodiment;

FIG. 3 is a graph for explaining an operation when a semiconductor switching element is normal and when the semiconductor switching element is turned on, in the power conversion device according to the first embodiment;

FIG. 4 is a graph for explaining an operation when the semiconductor switching element is normal and when the semiconductor switching element is turned on, in a power conversion device in a comparative example;

FIG. 5A is a graph for explaining an operation when the semiconductor switching element has experienced short-circuit break and when the semiconductor switching element is turned on, in the power conversion device in the comparative example;

FIG. 5B is a graph for explaining an operation when the semiconductor switching element is in a short-circuited state, in the power conversion device according to the first embodiment;

FIG. 6 is a graph for explaining an operation when the semiconductor switching element is normal and when the turn-on speed is higher than that in FIG. 3, in the power conversion device according to the first embodiment;

FIG. 7 is a graph for explaining an operation when the semiconductor switching element is normal and when the turn-on speed is lower than that in FIG. 3, in the power conversion device according to the first embodiment;

FIG. 8 is a graph for explaining an operation when the semiconductor switching element is in a short-circuited state and when the turn-on speed is higher than that in FIG. 5B, in the power conversion device according to the first embodiment;

FIG. 9 is a graph for explaining an operation when the semiconductor switching element is in a short-circuited state and when the turn-on speed is lower than that in FIG. 5B, in the power conversion device according to the first embodiment;

FIG. 10 is a graph for explaining operations which are performed when the semiconductor switching element is normal and among which the parasitic capacitance of a first diode 22 differs, in the power conversion device according to the first embodiment;

FIG. 11 is a circuit diagram showing another example of the main section of the power conversion device according to the first embodiment;

FIG. 12 is a circuit diagram showing an example of a main section of a power conversion device according to a second embodiment;

FIG. 13 is a circuit diagram showing another example of the main section of the power conversion device according to the second embodiment;

FIG. 14 is a graph for explaining an operation when the semiconductor switching element is normal and when the semiconductor switching element is turned on, in the power conversion device according to the second embodiment;

FIG. 15 is a graph for explaining an operation when the semiconductor switching element is in a short-circuited state, in the power conversion device according to the second embodiment; and

FIG. 16 is a block diagram showing an example of a specific configuration of each of drive circuitry and short-circuit determination circuitry in the present disclosure.

### DETAILED DESCRIPTION OF THE PREFERRED EMBODIMENTS OF THE INVENTION

### First Embodiment

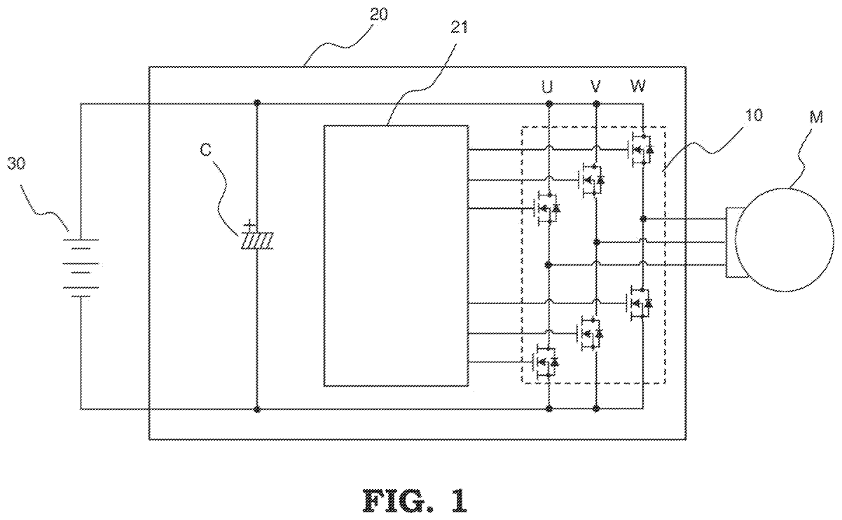

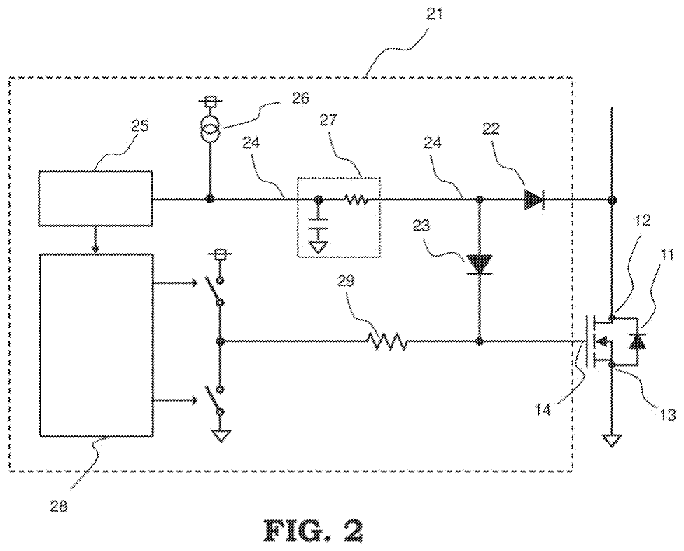

FIG. 1 is a circuit diagram showing a schematic configuration of a power conversion device 20 according to a first embodiment. FIG. 2 is a circuit diagram showing a main section. As shown in FIG. 1, the power conversion device 20 is intended to control a rotating electric machine M and includes: a power conversion circuit 10 composed of semiconductor switching elements on upper and lower arms for three phases (a U phase, a V phase, and a W phase); and a drive controller 21 which performs ON/OFF control on each of the semiconductor switching elements of the power conversion circuit 10. The power conversion device 20 further includes a smoothing capacitor C which is electrically connected in parallel to the high-potential side (drain) of the semiconductor switching elements on the upper arm and the low-potential side (source) of the semiconductor switching elements on the lower arm and which smooths a DC power supply voltage applied to the power conversion device 20. The power conversion device 20 converts DC power supplied from a DC power supply 30 into AC power and supplies the AC power to the rotating electric machine M to be controlled.

Although a MOSFET which has a drain and a source as main electrodes and in which the voltage of a gate is controlled so that current flowing between the drain and the source is controlled will be described below as an example of each semiconductor switching element, the semiconductor switching element may also be implemented by, for example, an IGBT which has a collector and an emitter as main electrodes and in which the voltage of a gate is controlled so that current flowing between the collector and the emitter is controlled. In the present disclosure, the drain or the collector is sometimes referred to as a first main electrode 12 (see FIG. 2), and the source or the emitter is sometimes referred to as a second main electrode 13 (see FIG. 2). That is, a semiconductor switching element 11 in the present disclosure has the first main electrode 12, the second main electrode 13, and a gate 14, and the power conversion device according to the present disclosure is a device that controls the voltage of the gate 14 with the second main electrode 13 of the semiconductor switching element 11 as a reference, to perform ON/OFF control for current flowing between the first main electrode 12 and the second main electrode 13 and perform power conversion between DC power and AC power.

Next, a detailed configuration of the power conversion device according to the first embodiment will be described with reference to FIG. 2. In the present first embodiment, the control configuration is basically the same among the three phases and between the upper and lower arms, and thus the lower arm for the U phase among these phases and arms will be described here. The semiconductor switching element 11 is provided on the lower arm for the U phase of the power conversion circuit 10, and the drive controller 21 performs ON/OFF control on the semiconductor switching element 11. The drive controller 21 includes: drive circuitry 28 which controls the voltage of the gate 14 of the semiconductor switching element 11; and short-circuit determination circuitry 25 which performs determination as to occurrence of short-circuit in the semiconductor switching element 11 and outputs an OFF command for the gate to the drive circuitry 28 when determining that short-circuit has occurred. The drive controller 21 further includes: a gate resistor 29; a first diode 22 having a cathode connected to the first main electrode (drain) 12 of the semiconductor switching element 11; a second diode 23 having a cathode connected to the gate 14 of the semiconductor switching element 11; and a current source 26 which supplies current in a direction (forward direction) from each of an anode of the first diode 22 and an anode of the second diode 23 toward the corresponding cathode. In addition, the short-circuit determination circuitry 25 and the current source 26 are connected to a wire 24 (a connection point between the anode of the first diode 22 and the anode of the second diode 23) to which the anode of the first diode 22 and the anode of the second diode 23 are connected.

As shown in FIG. 2, a filter 27 which suppresses influence of disturbance noise may be provided on the wire 24 (between the current source 26 and the connection point between the first diode 22 and the second diode 23). However, it is possible to arbitrarily determine whether or not to provide the filter 27 and at which position on the wire 24 the filter 27 is to be provided.

The semiconductor switching element 11 is a transistor made from silicon (Si) or a wide-bandgap semiconductor such as silicon carbide (SiC) or gallium nitride (GaN). As a gate voltage of the semiconductor switching element 11, a voltage equal to or higher than a predetermined voltage with the source of the semiconductor switching element 11 as a reference needs to be applied to the gate in order to turn on the semiconductor switching element 11. The predetermined voltage is called a mirror voltage. The mirror voltage is dependent on the type of the semiconductor switching element 11 and also on the amount of current caused to flow to the rotating electric machine M and is set to, for example, 10 V here.

As a drain voltage of the semiconductor switching element 11, a voltage equivalent to the DC power supply voltage is applied when the gate voltage is lower than the mirror voltage. The DC power supply voltage is, for example, 400 V in the case of a DC power supply voltage used for an electric automobile. Meanwhile, when the gate voltage is in a range of equal to or higher than the mirror voltage, the drain voltage is decreased to a voltage determined by the product of the ON resistance of the drain and a current caused to flow to the rotating electric machine M as a result of turning on the semiconductor switching element 11. In the present first embodiment, this voltage at the maximum current caused to flow to the rotating electric machine M is set to, for example, 10 V here.

With a configuration of connection between the first diode 22 and the second diode 23, the voltage of the wire 24 is determined by the lower one of the gate voltage and the drain voltage. For example, in a case where the gate voltage is lower than the mirror voltage, the drain voltage is 400 V, and thus the second diode 23 is turned on. Consequently, when the ON voltage (drop voltage at conduction) of the second diode 23 is assumed to be 0.5 V, the voltage of the wire 24 is 10.5 V at most. Meanwhile, in a case where the gate voltage is higher than the mirror voltage, the semiconductor switching element 11 is turned on, the drain voltage is decreased to 10 V or lower, and the first diode 22 is turned on. Consequently, when the ON voltage of the first diode 22 is assumed to be 0.5 V, the voltage of the wire 24 is 10.5 V at most.

Therefore, the short-circuit determination circuitry 25 can monitor the voltage of the wire 24 and determine, when detecting that the voltage of the wire 24 has become a voltage that is not reached in a normal operation, that the semiconductor switching element 11 is in a short-circuited state. That is, when the voltage at which a short-circuited state is determined to have been taken is defined as a threshold voltage, a voltage (e.g., 10.8 V) slightly higher than 10.5 V which is the sum of the mirror voltage of the gate and the ON voltage (i.e., drop voltage at conduction) of the second diode 23 may be set as a threshold voltage in the above example. When the short-circuit determination circuitry 25 detects that the voltage of the wire 24 has become a voltage higher than the threshold voltage, the short-circuit determination circuitry 25 determines that short-circuit has occurred, and the drive circuitry 28 sets the gate voltage to an OFF voltage. Consequently, short-circuit current can be prevented from flowing to the semiconductor switching element 11.

The amount of current to be supplied from the current source 26 can be arbitrarily determined as long as the amount does not influence drive in a normal state of the semiconductor switching element 11. The amount of current standardly used is about 1 mA. The current source 26 does not have to be a constant current source and may be of a type in which current having an amount that does not influence drive in a normal state of the semiconductor switching element 11 is supplied via a resistor from an arbitrarily-selected power supply at a voltage higher than the gate voltage.

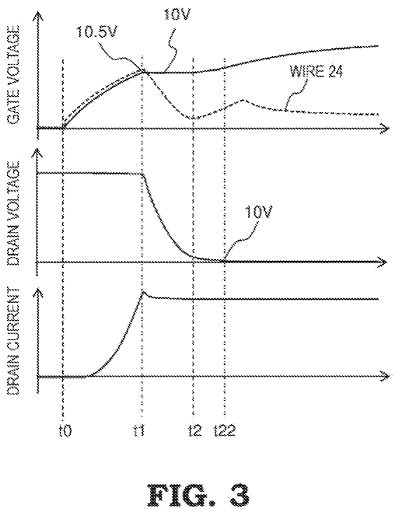

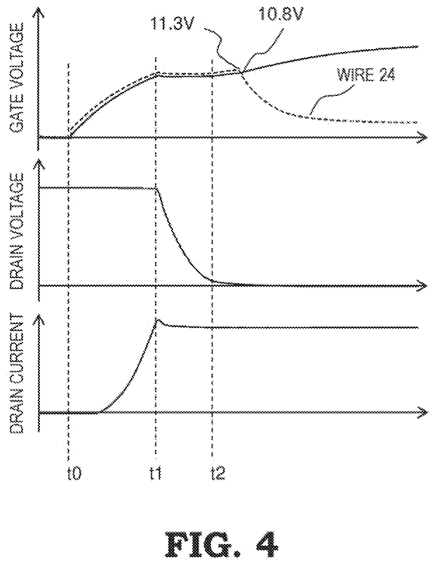

Firstly, FIG. 3 shows a gate voltage, a drain voltage, a drain current, and a voltage of the wire 24 when: the semiconductor switching element 11 is not in a short-circuited state and is in a normal state; and the state of the semiconductor switching element 11 is switched from an OFF state to an ON state. The gate voltage, the drain voltage, and the drain current are each indicated by a solid line, and the voltage of the wire 24 is indicated by a broken line together with the gate voltage indicated by a solid line. The same applies to FIG. 4 to FIG. 10 subsequently explained. In the following description, in consideration of variation in the ON voltage of the diode, the threshold voltage at which short-circuit is determined to have occurred is 10.8 V which is slightly higher than 10.5 V determined from the mirror voltage, the drain voltage, and the ON voltage of the diode which have been described above. Here, a case where the mirror voltage of the semiconductor switching element 11 is equal to or higher than a drain voltage in an ON state will be described. Meanwhile, in a case where the mirror voltage of the semiconductor switching element 11 is lower than the drain voltage in an ON state, the threshold voltage is desirably set to a voltage higher than the sum of the drain voltage in an ON state and the ON voltage of the first diode.

<Time Point t0 to Time Point t1>

The drive circuitry 28 starts to increase the gate voltage of the semiconductor switching element 11, and the gate voltage reaches the mirror voltage of 10 V at a time point t1. The voltage of the wire 24 is increased simultaneously, with an offset corresponding to the ON voltage of the second diode 23 relative to the gate voltage. Thus, the voltage of the wire 24 reaches 10.5 V at the time point t1. In this period, the drain voltage is kept at 400 V.

<Time Point t1 to Time Point t2>

Since the gate voltage has reached the mirror voltage, the semiconductor switching element 11 is turned on, and the drain voltage starts to drop steeply. In this period, the gate voltage is fixed at the mirror voltage of 10 V. This section is referred to as a mirror section. The time point at which the drain voltage is decreased to the ON voltage of 10 V is slightly later than a time point t2, and the drain voltage reaches 10 V at a time point t22. This is because, immediately after the time point t2 at which the mirror voltage has been crossed, the ON resistance of the semiconductor switching element 11 is still comparatively high, and the drain voltage has not been sufficiently decreased.

Here, focus should be placed on the feature in which the voltage of the wire 24 starts to be decreased simultaneously with the steep drop in the drain voltage at the time point t1 even though the drain voltage has not yet been decreased to the ON voltage of 10 V. A parasitic capacitance (Cst) (not shown in FIG. 2) generated between the anode and the cathode of the first diode 22 is related to this feature. This is because a discharge current corresponding to the product of Cst and a steep voltage fluctuation (dV/dt) generated in the cathode of the first diode 22 owing to the steep drop in the drain voltage is generated in a direction from the wire 24 toward the first main electrode 12 of the semiconductor switching element 11. When the amount of the discharge current is larger than the amount of current from the current source 26, the voltage of the wire 24 starts to be decreased at the time point t1.

For example, in a case where the parasitic capacitance Cst is 10 pF and the voltage fluctuation dV/dt is 1 kV/μs, the amount of the discharge current is 10 mA. Thus, in a case where the amount of current supplied from the current source 26 is 1 mA, a discharge effect of 9 mA corresponding to the difference between the amounts is obtained. Owing to this discharge, the voltage of the wire 24 is decreased simultaneously with start of decrease in the drain voltage.

FIG. 4 shows the voltage of the wire 24 when no parasitic capacitance is assumed to be present in the first diode 22. As shown in FIG. 4, the voltage of the wire 24 is not decreased between the time point t1 and the time point t2, and thus it is found that: the time point at which the voltage of the wire 24 starts to be decreased as a result of turning on the first diode 22 is later than the time point t2 at which the mirror voltage has been crossed; and, when the voltage starts to be decreased, the voltage is 11.3 V higher than 10.5 V obtained in the mirror section. This indicates that, in a case where it is assumed that there is no effect of discharge based on the parasitic capacitance Cst, erroneous determination occurs when the threshold voltage at which the short-circuit determination circuitry 25 determines that short-circuit has occurred is 10.8 V In this case, the threshold voltage needs to be set to 11.3 V or higher.

As described later, the threshold voltage for short-circuit determination is considered to be desirably low in order to quickly detect short-circuit and protect the semiconductor switching element 11, and discharge based on the parasitic capacitance Cst is considered to bring on an effect of shortening the detection time.

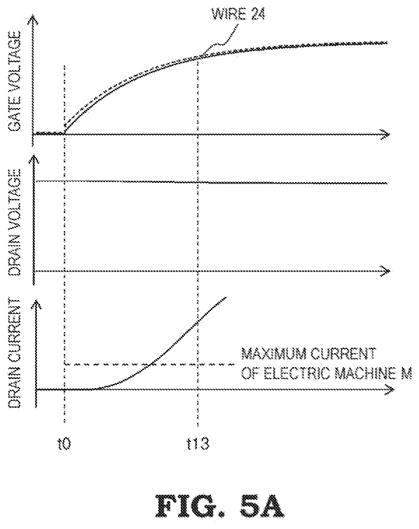

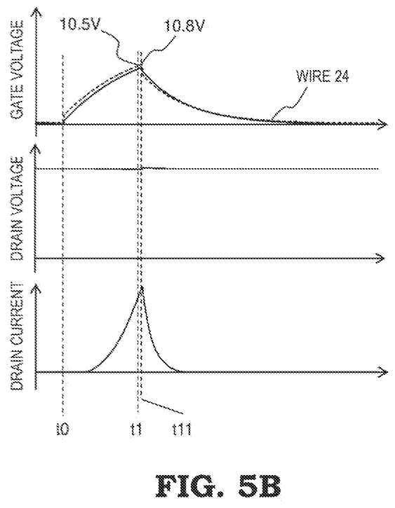

FIG. 5A and FIG. 5B each show an operation when short-circuit has occurred in the semiconductor switching element 11. FIG. 5A shows, as a comparative example of operation of the power conversion device according to the present first embodiment, an operation when short-circuit continues to occur without performing short-circuit detection. For example, a case is assumed where the first main electrode 12 of the semiconductor switching element 11 is electrically short-circuited with respect to the DC voltage source at 400 V for some reason. In this case, the gate voltage is increased, and short-circuit current is also increased together with the gate voltage. The short-circuit current becomes a high current much higher than the maximum current caused to flow to the rotating electric machine M and eventually becomes higher than a limit value for the semiconductor switching element 11, resulting in a short-circuit break state where restoration is difficult. With the time point at which the limit value is reached being denoted by t13, it is necessary to, within a period shorter than the period to the time point t13, perform short-circuit detection and turn off the gate voltage so as to interrupt short-circuit current, in order to achieve protection from short-circuit.

FIG. 5B shows an operation of the power conversion device according to the first embodiment, the operation being performed when short-circuit has occurred in the semiconductor switching element 11, the short-circuit determination circuitry 25 determines that short-circuit has occurred, and the drive circuitry 28 turns off the gate voltage. The gate voltage is increased, and the voltage of the wire 24 is also increased together with the gate voltage. When short-circuit has occurred in the semiconductor switching element 11, the voltage of the wire 24 is increased to the mirror voltage of 10V or a higher voltage obtained by adding the ON voltage of the second diode 23 to 10.5 V, unlike in FIG. 3 in which the semiconductor switching element 11 is normal. Here, the threshold voltage at which short-circuit is determined to have occurred is set to 10.8 V, and thus, at a time point t11 at which the voltage of the wire 24 reaches 10.8 V, short-circuit is determined to have occurred, and the drive circuitry 28 decreases the gate voltage to the OFF voltage simultaneously with this determination. Consequently, the drain current is decreased. According to a result obtained by the present inventors regarding the present first embodiment, the period to the time point t1 was 575 ns, and the period to the time point t11 at which the voltage of the wire 24 reached the threshold voltage (10.8 V) for short-circuit determination, i.e., the time for short-circuit detection, was 596 ns. That is, the detection delay time is 21 ns, thereby enabling detection at a high speed.

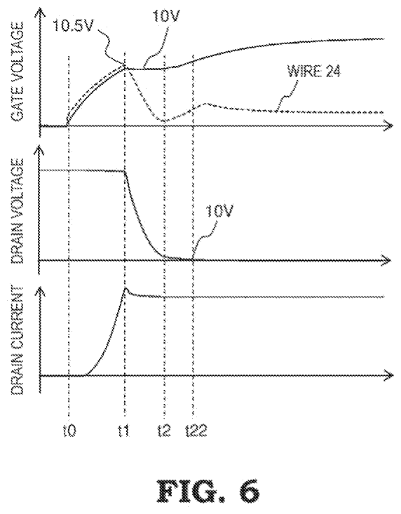

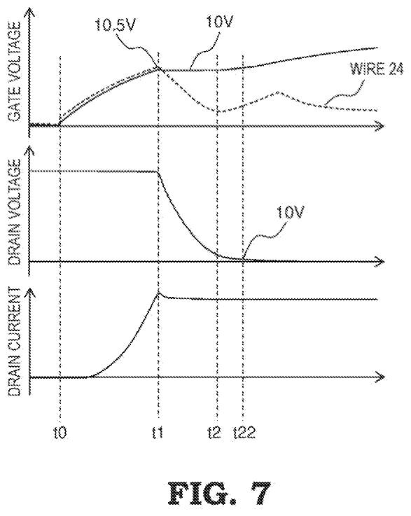

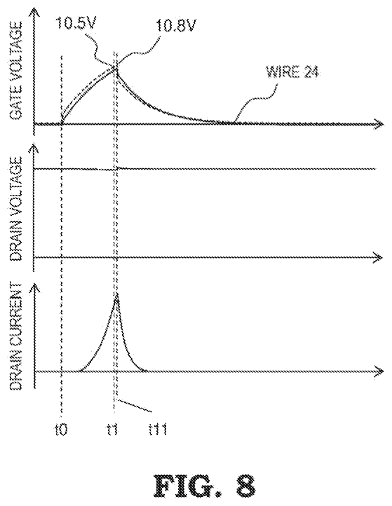

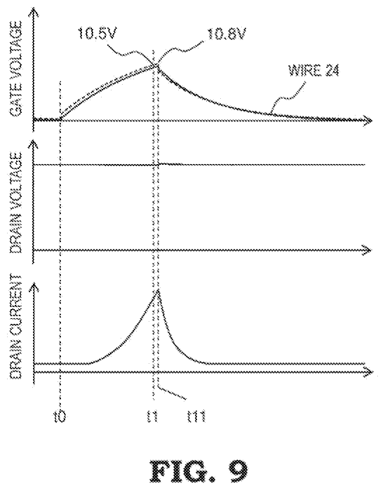

Next, operations among which the turn-on speed differs will be described. FIG. 6 and FIG. 7 show behaviors in the case of normal operations, and FIG. 8 and FIG. 9 show behaviors in the case of short-circuit. Firstly, as the behaviors in the case of normal operations, FIG. 6 shows a behavior in a state where the turn-on speed is higher than that in FIG. 3 by 30%, and FIG. 7 shows a behavior in a state where the turn-on speed is lower than that in FIG. 3 by the same degree, i.e., 30%. As shown in the drawings, it is found that: the voltage of the wire 24 is changed according to the turn-on speed, i.e., the speed of increase in the gate voltage; and the voltage of the wire 24 starts to be decreased at the time point t1 and does not reach the threshold voltage, whereby erroneous determination can be prevented.

Next, as the behaviors in short-circuit operations, FIG. 8 shows a behavior in a state where the turn-on speed is higher than that in FIG. 5B by 30%, and FIG. 9 shows a behavior in a state where the turn-on speed is lower than that in FIG. 5B by the same degree, i.e., 30%. In each of the cases, it is found that: the voltage of the wire 24 is increased until the time point t11 immediately subsequent to the time point t1 at which the gate voltage reaches 10.5 V; and short-circuit detection can be performed upon arrival at 10.8 V.

The following table 1 indicates the time points t1 and the time points t11 in FIG. 5B, FIG. 8, and FIG. 9 showing the behaviors in the case of short-circuit detection. The detection delay time corresponding to the period from the time point t1 to the time point t11 is also changed by a small amount according to the turn-on speed. Thus, the advantageous effect is improved or deteriorates depending on what turn-on speed is adopted in execution of drive control. However, this detection delay time is sufficiently shorter than 100 to 200 ns which are detection delay times generated in conventional technologies, and a more prominent effect is exhibited than those in the conventional technologies when drive control is performed with turn-on being achieved at an order of about 1 μs or lower.

TABLE 1

| | HIGH | | STANDARD | | LOW | |
|---|---|---|---|---|---|---|
| | TURN-ON | | TURN-ON | | TURN-ON | |
| | SPEED | | SPEED | | SPEED | |
| | (FIG. 8) | | (FIG. 5B) | | (FIG. 9) | |
| TIME POINT t1 | 412 | ns | 575 | ns | 709 | ns |
| TIME POINT t11 | 430 | ns | 596 | ns | 734 | ns |
| (DETECTION TIME) | | | | | | |
| DETECTION | 18 | ns | 21 | ns | 25 | ns |
| DELAY TIME | | | | | | |

In addition, Table 2 indicates times for short-circuit detection obtained with respect to respective different threshold voltages for short-circuit determination, in the present first embodiment. A lower threshold voltage makes it easier for the voltage of the wire 24 to reach the threshold voltage and results in a shorter time for short-circuit detection.

TABLE 2

| | THRESHOLD VOLTAGE | | | | |
|---|---|---|---|---|---|
| | 10.5 V | 10.8 V | 11.1 V | 11.3 V | 11.6 V |
| TIME POINT t11 | 569 ns | 596 ns | 628 ns | 651 ns | 683 ns |
| (DETECTION TIME) | | | | | |

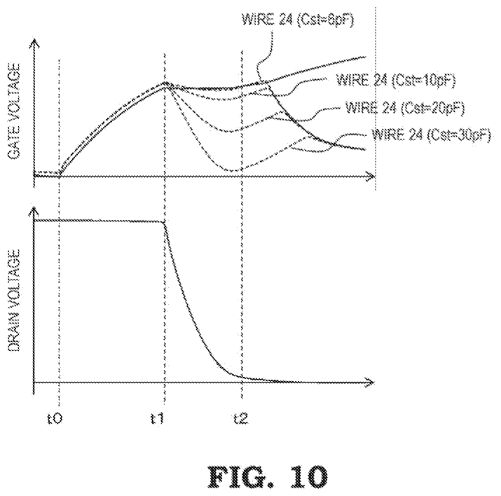

FIG. 10 shows changes, in the voltage of the wire 24, based on respective different discharge amounts based on respective different parasitic capacitances Cst. As described above, the discharge from the wire 24 based on the steep voltage fluctuation dV/dt and the parasitic capacitance Cst generated in the first diode 22 makes it easy to decrease the threshold voltage for short-circuit determination and contributes to shortening of the time for short-circuit detection.

As shown in FIG. 10, it has been concluded that, in the device in the present first embodiment conceived by the present inventors, a parasitic capacitance equal to or higher than about 10 pF is necessary for, at and subsequently to the time point t1, preventing erroneous determination and maintaining the voltage of the wire 24 to be a voltage lower than the threshold voltage in a state where the semiconductor switching element 11 is normal. However, the required parasitic capacitance value is considered to differ according to specifications of the semiconductor switching element 11. Therefore, when specifications of the semiconductor switching element 11 are determined, it is possible to, in a state where the semiconductor switching element 11 is normal, acquire characteristics such as ones in FIG. 10 and predetermine a parasitic capacitance value required for maintaining the voltage of the wire 24 to be a voltage lower than the threshold voltage. This result indicates that the parasitic capacitance value is an important factor in determining what kind of diode is to be selected. For example, the first diode 22 may be a Zener diode considered to have a comparatively high parasitic capacitance.

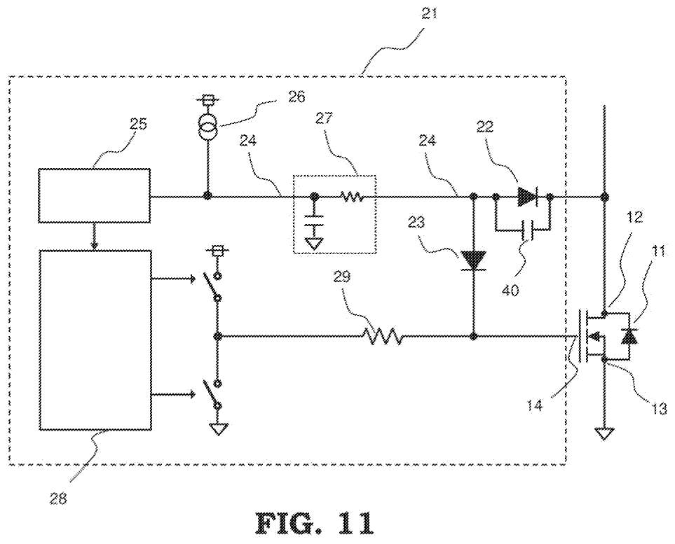

Alternatively, in a case where the parasitic capacitance of the first diode 22 is lower than the capacitance required for maintaining the voltage of the wire 24 to be a voltage lower than the threshold voltage, an additional capacitor 40 may be provided in parallel to the first diode 22 as shown in FIG. 11 such that the sum of the parasitic capacitance of the first diode 22 and the capacitance value of the additional capacitor 40 becomes equal to or higher than the capacitance required for maintaining the voltage of the wire 24 to be a voltage lower than the threshold voltage.

### Second Embodiment

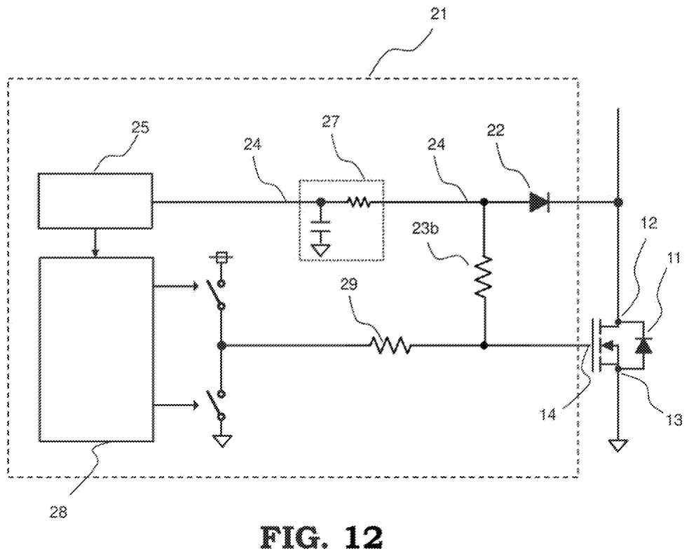

FIG. 12 is a circuit diagram showing a main section of a power conversion device 20 according to a second embodiment. The semiconductor switching element 11 is provided on the lower arm for the U phase of the power conversion circuit 10, and a drive controller 21 includes: the drive circuitry 28 which controls the voltage of the gate 14 of the semiconductor switching element 11 so as to perform ON/OFF control on the semiconductor switching element 11; the gate resistor 29; the first diode 22 having the cathode connected to the first main electrode (drain) 12 of the semiconductor switching element 11; a resistor 23b having one end connected to the gate 14 of the semiconductor switching element 11; the wire 24 (the connection point between the anode of the first diode 22 and the resistor 23b) to which the anode of the first diode 22 and another end, of the resistor 23b, on a side different from the gate 14 side are connected; and the short-circuit determination circuitry 25 which is connected to the wire 24, performs determination as to occurrence of short-circuit in the semiconductor switching element 11, and outputs an OFF command for the gate to the drive circuitry 28 when determining that short-circuit has occurred. Hereinafter, regarding a basic configuration and a basic control method of the power conversion device, detailed description of the same features as those in the first embodiment is omitted.

Similar to the first embodiment, regarding the filter 27 provided on the wire 24 shown in FIG. 12, it is possible to arbitrarily determine whether or not to provide the filter 27 and at which position on the wire 24 the filter 27 is to be provided.

The difference from the first embodiment is that: the second diode 23 is substituted with the resistor 23b; and the current source 26 is not provided. In this configuration as well, a time for short-circuit detection equivalent to that in the first embodiment can be expected to be obtained.

The manner in which the voltage of the wire 24 is determined with a configuration of connection between the first diode 22 and the resistor 23b will be specifically described. Here, description will be given with the mirror voltage of the gate being set to 10 V and with the drain voltage in an ON state being set to 10 V in the same manner as in the first embodiment.

For example, in a case where the gate voltage is lower than the mirror voltage, the voltage of the wire 24 can be raised by the resistor 23b so as to follow increase in the gate voltage despite the absence of the current source 26. Since the drain voltage is 400 V during this period, the wire 24 and the gate undergo changes at substantially the same potential. That is, since the mirror voltage is 10 V, the voltage of the wire 24 is also 10 V at most.

Meanwhile, in a case where the gate voltage is higher than the mirror voltage, the semiconductor switching element 11 is turned on, the drain voltage is decreased to 10 V or lower, and the first diode 22 is turned on. Consequently, when the ON voltage of the first diode 22 is assumed to be 0.5 V, the voltage of the wire 24 is 10.5 V at most.

A case is assumed where: the resistor 23b is absent; and the gate and the wire 24 are directly connected to each other. In this case, after the gate voltage reaches the mirror voltage and the first diode 22 is turned on, continuation of further increase of the gate voltage leads to conduction between the gate and the drain through the first diode 22. Consequently, it becomes difficult to perform desired gate drive for the semiconductor switching element 11. Thus, the resistor 23b has functions of: restricting conducting current generated between the gate and the drain when the semiconductor switching element 11 is turned on; and continuing the gate drive for the semiconductor switching element 11. Meanwhile, when the resistance value of the resistor 23b is excessively large, a filtering effect exhibited by the resistor 23b and the parasitic capacitance (not shown in FIG. 12) of the wire 24 makes it less likely for the voltage of the wire 24 to increase so as to follow the gate voltage when the gate is turned on. This consequence indicates that the voltage of the wire 24 reaches, at a later time point, the threshold voltage at which short-circuit is determined to have occurred. Thus, this consequence is undesirable. Therefore, the resistance value of the resistor 23b is desirably set to as small a value as possible within such a range that: the conducting current can be restricted; and the gate drive for the switching element 11 can be continued.

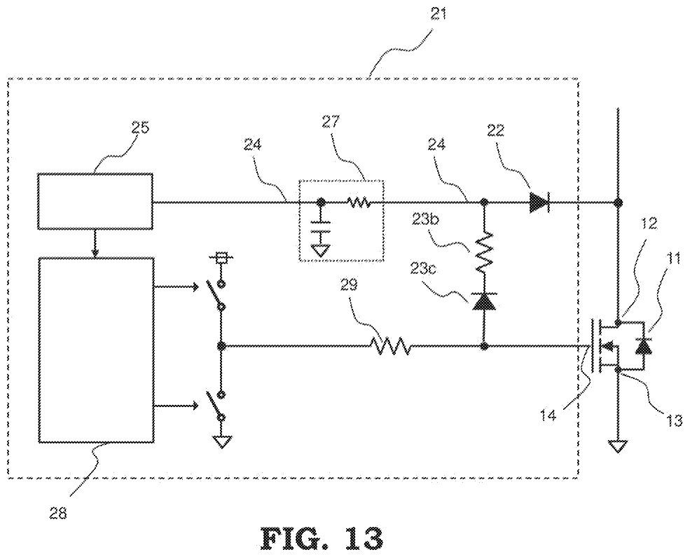

Although an example in which the gate and the wire 24 are connected to each other via one resistor 23b has been described here, a configuration may be employed in which, as shown in FIG. 13, a third diode 23c is connected in series to the resistor 23b such that a portion, of the third diode 23c, closer to the gate serves as an anode. In this configuration, current in a direction from the wire 24 toward the gate can be prevented. Thus, this configuration is effective in a case where there is a concern that reverse current that prevents the gate from being turned off flows from another circuit (not shown) connected to the wire 24, when the gate is turned off, for example.

Thus, in the same manner as in the first embodiment, the short-circuit determination circuitry 25 can monitor the voltage of the wire 24 and determine, when detecting that the voltage of the wire 24 has become a voltage that is not reached in a normal operation, that the semiconductor switching element 11 is in a short-circuited state. That is, when the voltage at which a short-circuited state is determined to have been taken is defined as a threshold voltage, a voltage (e.g., 10.8 V) slightly higher than 10.5 V may be set as a threshold voltage in the above example. When the short-circuit determination circuitry 25 detects that the voltage of the wire 24 has become a voltage higher than the threshold voltage, the short-circuit determination circuitry 25 determines that short-circuit has occurred, and the drive circuitry 28 sets the gate voltage to the OFF voltage. Consequently, short-circuit current can be prevented from flowing to the semiconductor switching element 11.

In the above example, the threshold voltage is set to 10.8 V since the voltage of the wire 24 determined from the drain voltage in an ON state is higher than the voltage of the wire 24 determined from the mirror voltage. However, it is also assumed that the voltage determined from the mirror voltage becomes higher depending on the type of the semiconductor switching element 11 or the maximum amount of current caused to flow to the rotating electric machine M.

For example, when the drain voltage in an ON state is assumed to be 8 V, the voltage of the wire 24 when the semiconductor switching element 11 is in an ON state is 8.5 V at most. Therefore, the voltage that the voltage of the wire 24 can reach in a normal operation is 10 V determined from the mirror voltage, and thus the threshold voltage only has to be set to 10 V or higher. In any case, in consideration of the first embodiment as well, it can be generally said that at least the threshold voltage is set to be higher than the maximum voltage of the wire 24 determined from the mirror voltage. In the configuration shown in FIG. 13 in which the third diode 23c is connected in series to the resistor 23b, the threshold voltage only has to be set to a voltage higher than a voltage value obtained by subtracting the drop voltage at conduction of the third diode 23c from the mirror voltage.

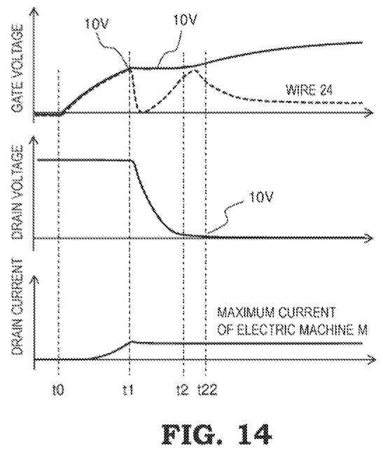

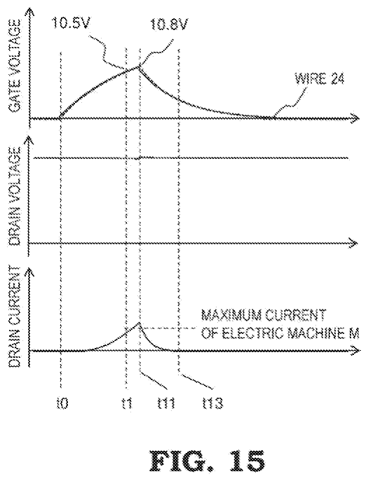

FIG. 14 shows a gate voltage, a drain voltage, a drain current, and a voltage of the wire 24 in the present second embodiment when: the semiconductor switching element 11 is not in a short-circuited state and is in a normal state; and the state of the semiconductor switching element 11 is switched from an OFF state to an ON state. The gate voltage, the drain voltage, and the drain current are each indicated by a solid line, and the voltage of the wire 24 is indicated by a broken line together with the gate voltage indicated by a solid line. The same applies to FIG. 15 subsequently explained. In the following description, in consideration of variation in the ON voltage of the diode, the threshold voltage at which short-circuit is determined to have occurred is 10.8 V which is based on 10.5 V determined from the mirror voltage, the drain voltage, and the ON voltage of the diode which have been described above.

During the period from the time point t0 to the time point t1, the gate voltage of the semiconductor switching element 11 is increased by the drive circuitry 28, and the gate voltage reaches the mirror voltage of 10 V at the time point t1. The voltage of the wire 24 is increased so as to substantially follow the gate voltage, and thus, reaches 10 V at the time point t1. In this period, the drain voltage is kept at 400 V.

At and subsequently to the time point t1, since the gate voltage has reached the mirror voltage, the semiconductor switching element 11 is turned on, and the drain voltage starts to drop steeply. At this time, the voltage of the wire 24 also starts to be decreased simultaneously with the steep drop in the drain voltage at the time point t1. This is because, in the same manner as in the first embodiment, the voltage of the wire 24 drops owing to a discharge current corresponding to the product of the parasitic capacitance (Cst) (not shown in FIG. 12) generated between the anode and the cathode of the first diode 22 and the steep voltage fluctuation (dV/dt) generated in the cathode of the first diode 22 owing to the steep drop in the drain voltage. In a case where the amount of the discharge current exceeds the amount of current supplied from the gate via the resistor 23b to the wire 24, the voltage of the wire 24 starts to be decreased at the time point t1 as in FIG. 14. In this manner, short-circuit is prevented from being erroneously determined to have occurred, also in the present second embodiment.

FIG. 15 shows an operation performed when, at the time of short-circuit in the semiconductor switching element 11, the short-circuit determination circuitry 25 determines that short-circuit has occurred, and the drive circuitry 28 turns off the gate voltage. The gate voltage is increased, and the voltage of the wire 24 is also increased together with the gate voltage. When short-circuit has occurred in the semiconductor switching element 11, the voltage of the wire 24 is increased to 10 V or higher unlike in FIG. 14 in which the semiconductor switching element 11 is normal. Here, the threshold voltage at which short-circuit is determined to have occurred is set to 10.8 V, and thus, at the time point t11 at which the voltage of the wire 24 reaches 10.8 V, short-circuit is determined to have occurred, and the drive circuitry 28 decreases the gate voltage to the OFF voltage simultaneously with this determination. Consequently, the drain current is decreased. According to a result obtained by the present inventors regarding the present second embodiment, the period to the time point t1 was 575 ns, and the period to the time point t11 at which the voltage of the wire 24 reached the threshold voltage (10.8 V) for short-circuit determination, i.e., the time for short-circuit detection, was 625 ns. That is, the detection delay time is 50 ns.

The obtained advantageous effect deteriorates as compared to the first embodiment in which the detection delay time is 21 ns. This deterioration occurs because the voltage of the wire 24 in the first embodiment is increased with a positive offset corresponding to the ON voltage of the second diode 23 relative to the gate voltage, whereas the voltage of the wire 24 in the present second embodiment is increased at substantially the same potential as that of the gate voltage, whereby it takes time to reach the same threshold voltage of 10.8 V. However, this drawback occurs because, as described above, each of the mirror voltage and the drain voltage in an ON state is set to 10 V, and the threshold voltage determined from the drain voltage is set to 10.8 V. In a case where the drain voltage in an ON state is lower than 10 V, the threshold voltage can be decreased. Thus, a time for short-circuit detection equivalent to that in the first embodiment can also be obtained depending on conditions.

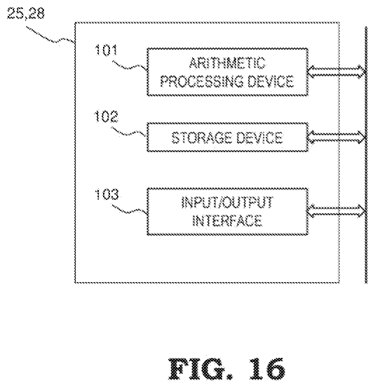

As shown in FIG. 16, each of the drive circuitry 28 and the short-circuit determination circuitry 25 in the drive controller 21 includes, for example, an arithmetic processing device 101 such as a central processing unit (CPU), a storage device 102 in which data is received from and transmitted to the arithmetic processing device 101; an input/output interface 103 through which a signal is inputted/outputted between the arithmetic processing device 101 and the outside; and the like. As the arithmetic processing device 101, an application specific integrated circuit (ASIC), an integrated circuit (IC), a digital signal processor (DSP), a field programmable gate array (FPGA), any type of signal processing circuit, or the like may be provided. As the storage device 102, a random access memory (RAM) configured to be able to read and write data with respect to the arithmetic processing device 101, a read only memory (ROM) configured to be able to read data from the arithmetic processing device 101, and the like are provided. Each of the drive circuitry 28 and the short-circuit determination circuitry 25 is realized through execution, by the arithmetic processing device 101, of a program saved in the storage device 102, for example. The input/output interface 103 is implemented by an interface for inputting a signal from outside to the arithmetic processing device 101, an interface for outputting a computation result from the arithmetic processing device 101 to outside, or the like.

The above description is summarized as follows. A first diode, a resistor or a second diode, and a function are provided. The first diode is connected to a first main electrode (drain) of a semiconductor switching element with the semiconductor switching element side of the first diode serving as a cathode. Between an anode of the first diode and a gate of the semiconductor switching element, the resistor is connected, or the second diode is connected with the gate side of the second diode serving as a cathode. The function is of determining, when the voltage of the anode of the first diode is higher than a threshold voltage, that short-circuit has occurred. Consequently, short-circuit is prevented from being erroneously determined to have occurred in an ordinary switching operation, and furthermore, short-circuit detection in a short time according to variation in the turn-on speed is realized without using any circuit having a delaying element such as a gate voltage detection circuit. In a case where the second diode is connected between the anode of the first diode and the gate of the semiconductor switching element with the gate side of the second diode serving as a cathode, a current source which supplies current in a direction from each of the anode of the first diode and an anode of the second diode toward the corresponding cathode, is necessary.

The following measure is taken to further shorten the time for short-circuit detection. That is, a diode is selected such that, immediately after the gate voltage reaches the mirror voltage, the voltage of the wire is decreased owing to discharge of electric charge with which the parasitic capacitance of the diode has been charged, and the threshold voltage at which short-circuit is determined to have occurred is set to the sum of the mirror voltage and the conduction voltage of the diode.

In these technologies, as the semiconductor switching element, a conventional insulated-gate bipolar transistor (IGBT) containing silicon (Si) as a main component may be used. However, the advantageous effects are more prominently exhibited by using, as the semiconductor switching element, a metal-oxide-semiconductor field-effect transistor (MOSFET) which is a semiconductor switching element made from a wide-bandgap semiconductor. The wide-bandgap semiconductor is considered to become widespread in the future, contains silicon carbide (SiC) or gallium nitride (GaN) as a main component, and has a wider bandgap than silicon. The reason for the more prominent exhibition of the advantageous effects is as follows. That is, upon a short-circuit failure, short-circuit current rapidly flows through the wide-bandgap semiconductor because of a low ON resistance thereof, and short-circuit detection is required to be quickly completed for protection.

As described above, the power conversion device according to the present disclosure makes it possible to provide a power conversion device including a short-circuit determination circuit that is prevented from erroneously determining, in a normal switching operation of a semiconductor switching element, that short-circuit has occurred, the short-circuit determination circuit having a decreased delay time required for short-circuit determination when short-circuit has occurred in the semiconductor switching element, the short-circuit determination circuit thus requiring a short detection time.

Although the present disclosure is described above in terms of various exemplary embodiments and implementations, it should be understood that the various features, aspects and functionality described in one or more of the individual embodiments are not limited in their applicability to the particular embodiment with which they are described, but instead can be applied, alone or in various combinations to one or more of the embodiments.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

What is claimed is:

1. A power conversion device which has a semiconductor switching element having a first main electrode, a second main electrode, and a gate and which controls a voltage of the gate with the second main electrode as a reference, to perform ON/OFF control for current flowing between the first main electrode and the second main electrode and perform power conversion between DC power and AC power, the power conversion device comprising:
a first diode having a cathode connected to the first main electrode;
a second diode having an anode and a cathode respectively connected to an anode of the first diode and the gate;
a current source which supplies current through a connection point between the anode of the first diode and the anode of the second diode, in a direction from each of the anode of the first diode and the anode of the second diode toward the corresponding cathode;
drive circuitry which controls the voltage of the gate of the semiconductor switching element; and
short-circuit determination circuitry which determines whether or not short-circuit has occurred in the semiconductor switching element, wherein
the short-circuit determination circuitry determines, when a voltage of the connection point between the first diode and the second diode is higher than a threshold voltage, that short-circuit has occurred in the semiconductor switching element, and
the drive circuitry sets, when the short-circuit determination circuitry determines that short-circuit has occurred, the voltage of the gate to a voltage for turning off the semiconductor switching element.

2. The power conversion device according to claim 1, wherein the threshold voltage is set to a voltage higher than a sum of a mirror voltage, of the gate, at which the semiconductor switching element starts to be in an ON state and a drop voltage at conduction of the second diode.

3. A power conversion device which has a semiconductor switching element having a first main electrode, a second main electrode, and a gate and which controls a voltage of the gate with the second main electrode as a reference, to perform ON/OFF control for current flowing between the first main electrode and the second main electrode and perform power conversion between DC power and AC power, the power conversion device comprising:
a first diode having a cathode connected to the first main electrode;
a resistor connected between an anode of the first diode and the gate;
drive circuitry which controls the voltage of the gate of the semiconductor switching element; and
short-circuit determination circuitry which determines whether or not short-circuit has occurred in the semiconductor switching element, wherein
the short-circuit determination circuitry determines, when a voltage of the anode of the first diode is higher than a threshold voltage, that short-circuit has occurred in the semiconductor switching element, and
the drive circuitry sets, when the short-circuit determination circuitry determines that short-circuit has occurred, the voltage of the gate to a voltage for turning off the semiconductor switching element.

4. The power conversion device according to claim 3, wherein the threshold voltage is set to be higher than a mirror voltage, of the gate, at which the semiconductor switching element starts to be in an ON state.

5. The power conversion device according to claim 3, further comprising a third diode connected between the anode of the first diode and the gate in series to the resistor, with the gate side of the third diode serving as an anode.

6. The power conversion device according to claim 5, wherein the threshold voltage is set to be higher than a voltage value obtained by subtracting a drop voltage at conduction of the third diode from a mirror voltage, of the gate, at which the semiconductor switching element starts to be in an ON state.

7. The power conversion device according to claim 1, wherein the first diode is a diode having, between the anode and the cathode thereof, a parasitic capacitance equal to or higher than a capacitance value predetermined such that a voltage of the anode of the first diode is maintained to be equal to or lower than the threshold voltage when the semiconductor switching element is in a normal state.

8. The power conversion device according to claim 3, wherein the first diode is a diode having, between the anode and the cathode thereof, a parasitic capacitance equal to or higher than a capacitance value predetermined such that a voltage of the anode of the first diode is maintained to be equal to or lower than the threshold voltage when the semiconductor switching element is in a normal state.

9. The power conversion device according to claim 1, further comprising a capacitor connected in parallel to the first diode.

10. The power conversion device according to claim 3, further comprising a capacitor connected in parallel to the first diode.

11. The power conversion device according to claim 1, wherein a material of the semiconductor switching element is a wide-bandgap semiconductor.

12. The power conversion device according to claim 3, wherein a material of the semiconductor switching element is a wide-bandgap semiconductor.
